(19) United States
(12) Patent Application Publication
(10) Pub. No.: US 2001/0006244 A1
(43) Pub. Date: Jul. 5, 2001

(54) Element isolating method in semiconductor integrated circuit device, semiconductor integrated circuit device and manufacturing method thereof

(75) Inventors: Masakuni Shimizu, Tokyo (JP); Eiji Io, Tokyo (JP)

Correspondence Address: Norman P. Soloway, HAYES, SOLOWAY, HENNESSEY,, GROSSMAN & HAGE, P.C., 175 Canal Street, Manchester, NH, 03101, US

(73) Assignee: NEC CORPORATION

(21) Appl. No.: 09/733,393

(22) Filed: Dec. 11, 2000

(30) Foreign Application Priority Data
Dec. 9, 1999 (JP) 350515/1999

(51) Int. Cl. H01L 21/8238; H01L 21/336; H01L 27/108; H01L 29/76; H01L 31/119; H01L 29/00; H01L 21/331

(52) U.S. Cl. 257/501; 257/510; 257/296; 438/221; 438/296; 438/353; 438/218; 438/294

(57) ABSTRACT

A first isolating trench with a predetermined depth is formed in a region where high voltage semiconductor elements are formed on a semiconductor substrate, and a portion of the walls of the first isolating trench is etched corresponding to a depth of a second isolating trench shallower than the first isolating trench to form a third isolating trench. An oxide film filled into the third isolating trench provides isolation between the high voltage semiconductor elements. Then, the second isolating trench is formed in a region where low voltage semiconductor elements are formed, and an oxide film filled into the second isolating trench is used to provide isolation between the low voltage semiconductor elements.

### BACKGROUND OF THE INVENTION

1. Field of the Invention

The present invention relates to an element isolating method for providing isolation between elements mounted in a semiconductor integrated circuit device, and more particularly to an element isolating method in a semiconductor integrated circuit device in which a semiconductor element such as a nonvolatile memory to which a high voltage is applied and a semiconductor element such as a logical circuit to which a low voltage is applied are mounted together.

2. Description of the Related Art

A semiconductor integrated circuit device in recent years does not have features such as a CPU, logical circuit and memory as individual units, but a tendency is accelerated toward SOC (System On Chip) in which those features are mounted on a single chip to constitute one system.

As a memory mounted on such a semiconductor integrated circuit device, a flash EEPROM (Electrically Erasable Programmable Read-Only Memory) which facilitates a higher degree of integration with nonvolatility is used, for example.

The flash EEPROM which is a nonvolatile semiconductor memory and allows electrical writing/reading of data has, for example, a known structure which includes a plurality of cell transistors each having a floating gate electrode and a control gate electrode at memory cell portions for storing data and transistors for control such as a high voltage transistor or a select transistor for controlling/selecting the cell transistors.

Since a relatively high voltage of 10 V to 20 V is applied to some of such cell transistors or control transistors for writing or erasing data, it is necessary that a field oxide film formed in an element isolating area for providing isolation between such elements has a thickness of 400 to 500 nm.

On the other hand, a transistor for a logical circuit used in a semiconductor integrated circuit device in recent years tends to have lower withstand voltage with its increasingly finer size, and a power supply voltage is reduced. A thickness of approximately 100 to 200 nm is sufficient for a field oxide film formed in an element isolating area for providing isolation between such elements (at a power supply voltage of 2.5 to 5.0 V).

Conventionally, a semiconductor integrated circuit device which has plural types of semiconductor elements with different applied voltages mounted therein employs a method (hereinafter referred to as “first prior art”) in which trenches with a uniform depth (hereinafter referred to as “STI (Shallow Trench Isolation)”) are formed in an element isolating area and an oxide film is filled therein for providing isolation between elements, or a method (hereinafter referred to as “second prior art”) in which STI with a desired depth is first formed only in a region requiring high withstand voltage and then STI with a smaller depth is formed in a region in which logical circuits are formed and oxide films are filled therein with appropriate thicknesses for the respective regions for providing isolation between elements.

Description is made for the procedure to manufacture a semiconductor integrated circuit device with these element isolating methods of the first prior art and the second prior art. It should be noted that in the following description, a region in which a nonvolatile memory is formed is referred to as “nonvolatile memory region”, a region in which a transistor requiring high withstand voltage is formed as “high voltage transistor region”, and a region in which a transistor requiring low withstand voltage such as a transistor for a logical circuit is formed as “logical circuit region”.

First, the manufacturing procedure of a semiconductor integrated circuit device with the element isolating method of the first prior art is described with reference to FIG. 1.

As shown in FIG. 1, in the first prior art, silicon oxide (SiO₂) film 302 with a thickness of approximately 10 nm is first deposited on Si substrate 301, and silicon nitride (Si₃N₄) film 303 with a thickness of approximately 150 nm is deposited thereon. Subsequently, photoresist 304 is deposited on silicon nitride film 303 and photoresist 304 is patterned in order to form element isolating areas using a photolithography technique (FIG. 1 (a)).

Next, the parts of silicon nitride film 303 and silicon oxide film 302 are removed in the openings in photoresist 304 with a plasma etching process, respectively, and Si substrate 301 is etched, thereby forming isolating trenches 305 with a depth of approximately 500 nm (FIG. 1(b)). Then, photoresist 304 on silicon nitride film 303 is removed, and inside wall thermal oxide film 305a with a thickness of approximately 20 to 30 nm is formed on the bottom surfaces and side surfaces of isolating trenches 305 with a thermal oxidation process.

Next, plasma oxide film 308 is deposited with a plasma CVD (Chemical Vapor Deposition) process such that plasma oxide film 308 is embedded in isolating trenches 305 (FIG. 1(c)). The top surface of embedded plasma oxide film 308 is planarized with a CMP (Chemical Mechanical Polishing) process to expose silicon nitride film 303 (FIG. 1(d)). In addition, silicon nitride film 303 and silicon oxide film 302 on Si substrate 301 are removed with a wet etching process, respectively (FIG. 1(e)). In this manner, field oxide films with an equal film thickness are formed in respective element isolating areas in a nonvolatile memory region, a high voltage transistor region, and a logical circuit region.

When the element isolation with the field oxide films is completed, tunneling oxide film 309, floating gate electrode 310 and ONO (Oxide Nitride Oxide) film 311 which is an insulating film for insulating floating gate electrode 310 from a control gate electrode are formed for a cell transistor in the nonvolatile memory region, and gate oxide films 313 for respective transistors are formed in the high voltage transistor region and the logical circuit region. Also, control gate electrode 312 for a cell transistor is formed, and gate electrodes 314 for transistors are formed in the high voltage transistor region and the logical circuit region (FIG. 1(f)). Subsequently, impurity diffusion layers, not shown, which are to serve as sources and drains for respective transistors, are formed, and wiring steps follow.

In the first prior art, since all isolating trenches 305 are formed to have uniform depths (approximately 500 nm) in accordance with the element isolating performance required in the nonvolatile memory region and the high voltage transistor region, the element isolating width in the logical circuit region is approximately 0.5 μm similarly to the nonvolatile memory region and the high voltage transistor region. The width of the field oxide film formed in the element isolating area is determined by the embedding properties of the oxide film, and controlled by the depth of isolating trench 305 formed with the plasma etching. When the depth of isolating trench 305 is determined in accordance with the element isolating performance required in the logical circuit region, the element isolating width is 0.2 to 0.3 μm if the depth of the isolating trench is 200 to 300 nm in consideration of a reduction in the film thickness in subsequent steps, for example.

Next, the manufacturing procedure of a semiconductor integrated circuit device with the element isolating method of the second prior art is described with reference to FIG. 2.

As shown in FIG. 2, in the second prior art, silicon oxide film 402 with a thickness of approximately 10 nm is first deposited on Si substrate 401 similarly to the first prior art, and then silicon nitride film 403 with a thickness of approximately 150 nm is deposited thereon (FIG. 2(a)). Subsequently, first photoresist 404 is deposited on silicon nitride film 403, and first photoresist 404 is patterned in order to form element isolating areas in a nonvolatile memory region and a high voltage transistor region using a photolithography technique (FIG. 2(b)).

Next, the parts of silicon nitride film 403 and silicon oxide film 402 are removed in the openings in first photoresist 404 with the plasma etching process, respectively, and Si substrate 401 is etched, thereby forming first isolating trenches 405 with a thickness of approximately 500 nm (FIG. 2(c)).

Subsequently, after first photoresist 404 on silicon nitride film 403 is removed, second photoresist 406 is deposited on silicon nitride film 403 such that first isolating trenches are embedded. Then, second photoresist 406 is patterned in order to form an element isolating area in a logical circuit region using a photolithography technique (FIG. 2(d)).

Next, the parts of silicon nitride film 403 and silicon oxide film 402 are removed in the openings in second photoresist 406 with the plasma etching process, respectively, and Si substrate 401 is etched, thereby forming second isolating trenches 407 with a thickness of approximately 300 nm (FIG. 2(e)).

Subsequently, second photoresist 406 on silicon nitride film 403 is removed, and inside wall thermal oxide films 405a and 407a are deposited with a thickness of 20 to 30 nm on the bottom surfaces and side surfaces of first isolating trenches 405 and second isolating trenches 407 with the thermal oxidation process, respectively. Then, plasma oxide film 408 is deposited with the plasma CVD process such that plasma oxide film 408 is embedded in first isolating trenches 405 and second isolating trenches 407, respectively (FIG. 2(f)).

Next, plasma oxide film 408 is planarized with the CMP process to expose silicon nitride film 403 (FIG. 2(g)), and finally, silicon nitride film 403 and silicon oxide film 402 on Si substrate 401 are removed with the wet etching process, respectively (FIG. 2(h)).

In this manner, field oxide films with appropriate thickness for the respective element isolating areas are formed in the nonvolatile memory region, the high voltage transistor region, and the logical circuit region.

When the element isolation with the field oxide films is completed, tunneling oxide film 409, floating gate electrode 410 and ONO film 411 which is an insulating film for insulating floating gate electrode 410 from a control gate electrode are formed for a cell transistor in the nonvolatile memory region, and gate oxide films 413 for respective transistors are formed in the high voltage transistor region and the logical circuit region. Then, control gate electrode 412 for a cell transistor is formed, and gate electrodes 414 for transistors are formed in the high voltage transistor region and the logical circuit region (FIG. 2(i)). Subsequently, impurity diffusion layers, not shown, which are to serve as sources and drains for respective transistors, are formed, and wiring steps follow.

Of the aforementioned element isolating methods for a semiconductor integrated circuit device of the prior arts, in the element isolating method of the first prior art, when the isolating trenches are formed to have uniform depths in accordance with the element isolating performance in the nonvolatile memory region and the high voltage transistor region as described above, the existing manufacturing process of logical circuits requires modifications and reconfiguration.

In addition, associated therewith, it is necessary to increase the element isolating width in the logical circuit region in view of the issue of the embedding properties of the plasma oxide film in the isolating trench. This causes the problem of a reduced degree of integration in the logical circuit region and the problem of the inability to use design resources in the existing logical circuit portion.

In contrast, when the isolating trenches are formed to have uniform depths in accordance with the element isolating performance in the logical circuit region, it is necessary to increase the element isolating width for ensuring the element isolating performance in the nonvolatile memory region and the high voltage transistor region. This leads to an increased area occupied by the nonvolatile memory region and the high voltage transistor region to cause the problem of a reduced degree of integration.

Another approach is contemplated in which the field oxide films are reduced in thickness in the nonvolatile memory region and the high voltage transistor region by applying a lower voltage to the nonvolatile memory and the high voltage transistor to eliminate the need for high withstand voltage. This approach, however, inevitably involves deteriorated performance of the nonvolatile memory due to an increase in time for writing data to and erasing data from a memory cell.

On the other hand, in the element isolating method of the second prior art, the formation of two lower components on a single Si substrate increases misalignment of masks for exposure, and particularly, the problem of a significantly smaller manufacturing margin (margin for misalignment) occurs at the formation of an upper component (for example, a contact for connecting a wiring pattern with an electrode for a transistor).

Specifically, in the element isolating method of the first prior art, since the field oxide films can be formed at a time in the nonvolatile memory region, high voltage transistor region and logical circuit region, floating gate electrode 310 and control gate electrode 312 for a memory cell, gate electrode 314 of a transistor for a logical circuit, and contact 317 are formed within uniform errors, respectively, with respect to the position of isolating trenches 305 as shown in FIG. 3. The arrows in FIG. 3 indicate errors due to misalignment of positions where the respective components are formed. Therefore, even with a normal manufacturing margin, floating gate electrode 310 and control gate electrode 312 for a memory cell, or gate electrode 314 of a transistor for a logical circuit and contact 317 are formed not to overlap each other. In addition, upper electrode 318 serving as wiring formed on interlayer insulating film 316 is connected reliably to contact 317.

In the element isolating method of the second prior art, however, isolating trenches 407 in the logical circuit region are formed with a predetermined positional error with respect to the positions of isolating trenches 405 in the nonvolatile memory region and high voltage transistor region as shown in FIG. 4, and gate electrode 414 of a transistor for a logical circuit and contact 417 are formed with a predetermined positional error with respect to those isolating trenches 407 in the logical circuit region. Therefore, with a normal manufacturing margin, floating gate electrode 410 and control gate electrode 412 for a memory cell may be formed to overlap contact 417 (shown as “X” in FIG. 4).

When the contacts in the two regions are individually formed to avoid the overlap between contact 417 and control gate electrode 412, a poor connection may occur between upper electrode 418 serving as wiring formed on interlayer insulating film 416 and contact 417 to result in an increased rate of occurrence of defective products at the manufacturing.

### SUMMARY OF THE INVENTION

In view of the aforementioned problems, it is an object of the present invention to provide an element isolating method in a semiconductor integrated circuit device which involves no deterioration of performance of transistors for a nonvolatile memory or logical circuits, maintains the existing design scheme in transistors for logical circuits, and allows a finer size of the nonvolatile memory or high voltage transistors without impairing a manufacturing margin.

To achieve the aforementioned object, in the present invention, a first isolating trench with a predetermined depth is formed in a region where high voltage semiconductor elements are formed on a semiconductor substrate, and a portion of the walls of the first isolating trench is etched corresponding to a depth of a second isolating trench shallower than the first isolating trench to form a third isolating trench. An oxide film filled into the third isolating trench provides isolation between the high voltage semiconductor elements. Then, the second isolating trench is formed in a region where low voltage semiconductor elements are formed, and an oxide film filled into the second isolating trench is used to provide isolation between the low voltage semiconductor elements.

With such a configuration, since it is possible to form field oxide films comprising oxide films with desired thicknesses respectively in the region where the high voltage semiconductor elements are formed, the element isolating performance can be maintained even in the region requiring high withstand voltage. In addition, since a field oxide film in a low voltage semiconductor element such as a transistor for a logical circuit can be set to have the existing thickness, the element isolating steps need not be changed and a reduced degree of integration can be prevented, thereby allowing the existing manufacturing process and existing design resources to be utilized. Moreover, the positions of respective element isolating areas are determined by the positions of the simultaneously formed second isolating trenches, and the increased number of lower components causes no increase in misalignment of masks for exposure. Thus, a smaller manufacturing margin can be prevented.

In addition, in the present invention, a polysilicon film serving as an electrode and an oxide film with a predetermined thickness on the polysilicon film are filled into the isolating trench, and the isolation between the semiconductor elements is provided by the polysilicon film to which a predetermined voltage is applied and the oxide film.

With this configuration, it is possible to significantly enhance withstand voltage for isolation between semiconductor elements as compared with the case where only the oxide film is provided, and predetermined element isolating performance can be obtained even with a thinner oxide film formed in the element isolating area.

The above and other objects, features, and advantages of the present invention will become apparent from the following description with reference to the accompanying drawings which illustrate examples of the present invention.

### BRIEF DESCRIPTION OF THE DRAWINGS

FIG. 1 is a cross sectional view of a semiconductor integrated circuit device illustrating an element isolating method of a first prior art;

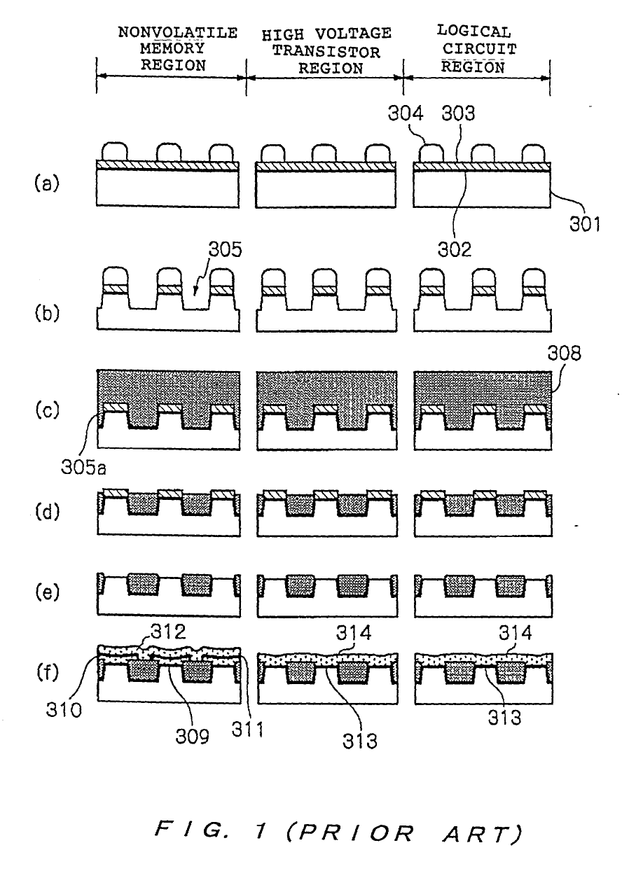

FIG. 2 is a cross sectional view of a semiconductor integrated circuit device illustrating an element isolating method of a second prior art;

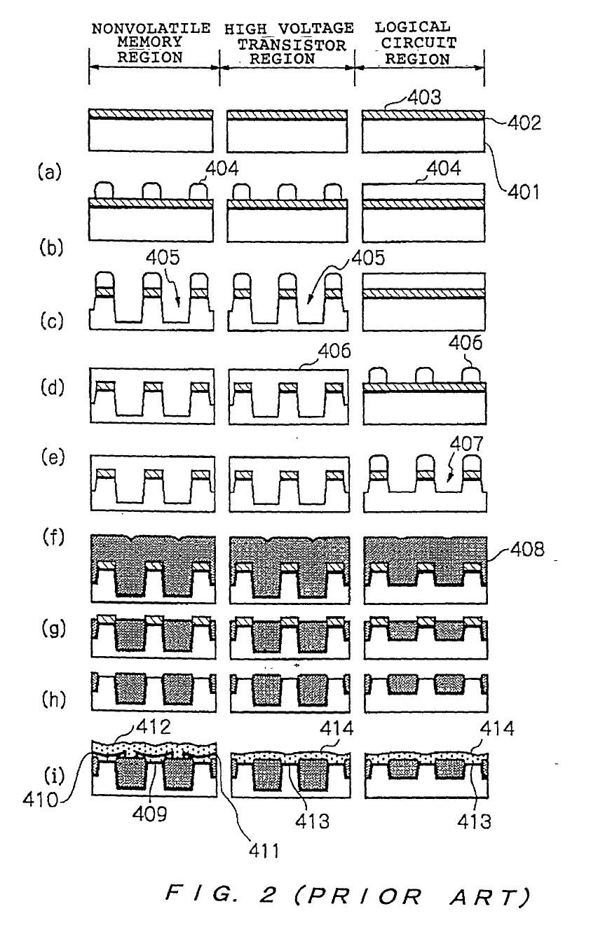

FIG. 3 is a cross sectional view showing enlarged main portions of the semiconductor integrated circuit device of the first prior art;

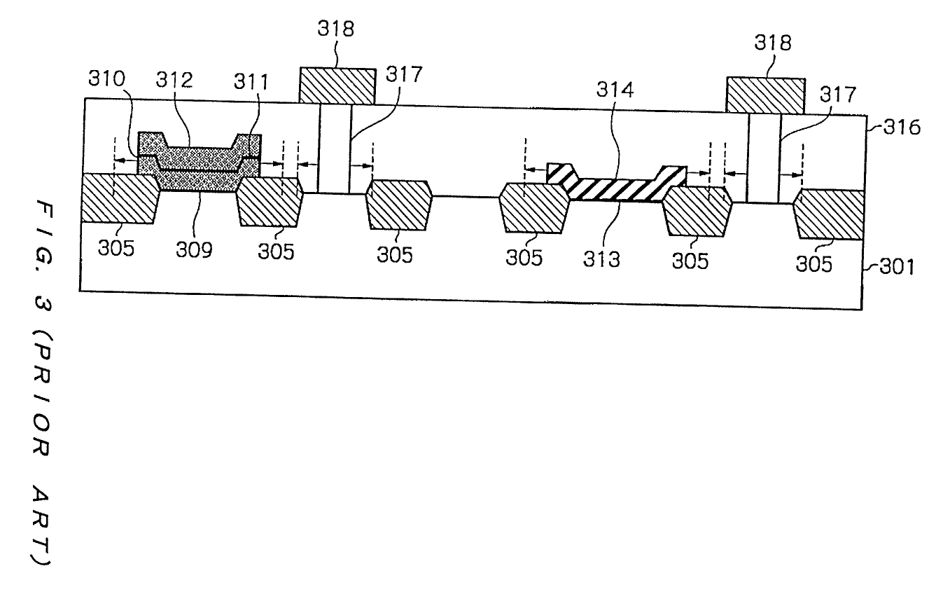

FIG. 4 is a cross sectional view showing enlarged main portions of the semiconductor integrated circuit device of the second prior art;

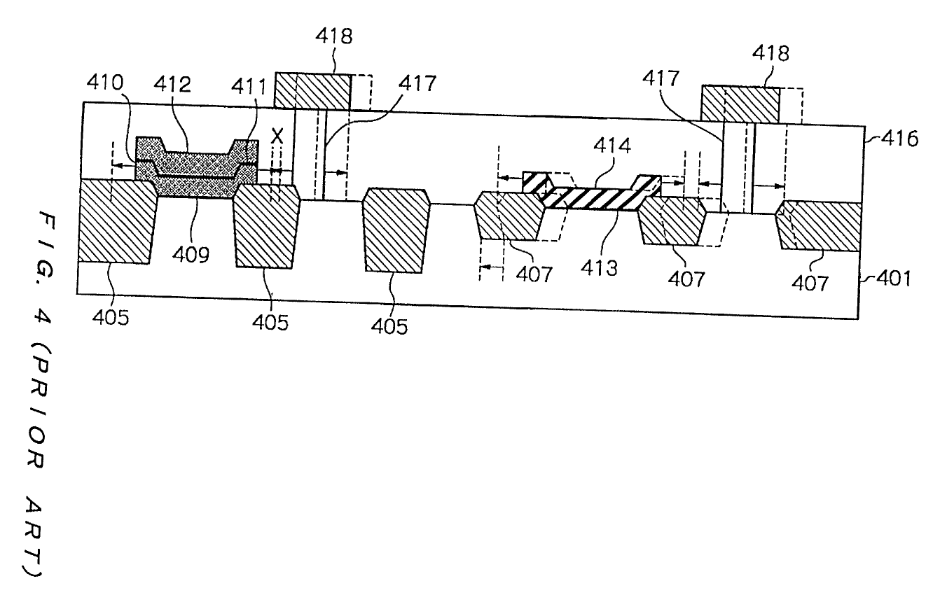

FIG. 5 is a cross sectional view of a semiconductor integrated circuit device illustrating a first embodiment of an element isolating method of the present invention; and

FIG. 6 is a cross sectional view of a semiconductor integrated circuit device illustrating a second embodiment of the element isolating method of the present invention.

### DETAILED DESCRIPTION OF THE PREFERRED EMBODIMENTS

(First Embodiment)

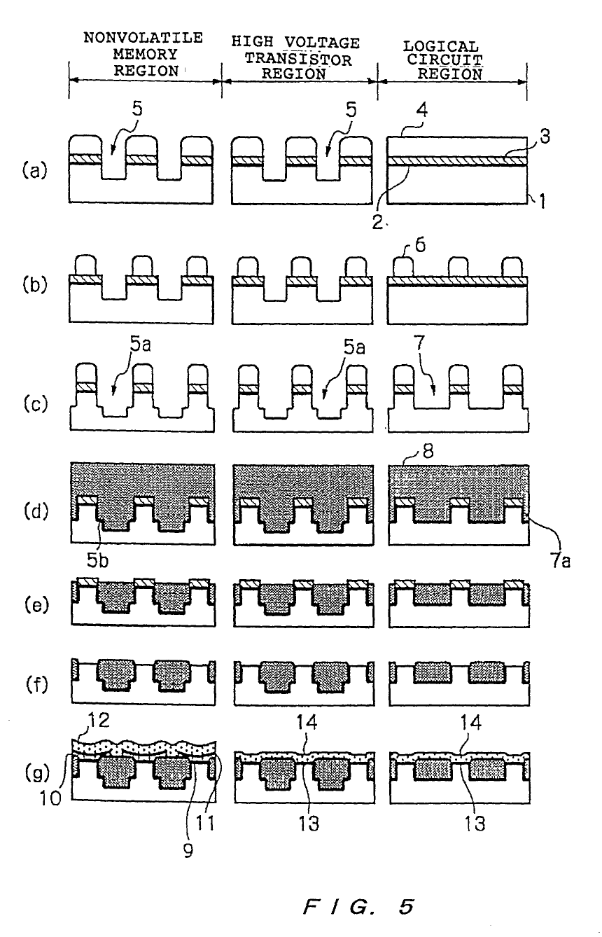

A first embodiment of an element isolating method in a semiconductor integrated circuit device according to the present invention is hereinafter described with reference to FIG. 5.

As shown in FIG. 5, in the first embodiment, silicon oxide film 2 with a thickness of approximately 10 nm is first deposited on Si substrate 1, and silicon nitride film 3 with a thickness of approximately 150 nm is deposited thereon. Subsequently, first photoresist 4 is deposited on silicon nitride film 3, and first photoresist 4 is patterned in order to form isolating trenches with a depth required for a nonvolatile memory region and a high voltage transistor region using a photolithography technique. First photoresist 4 is patterned to form the openings of a smaller width than a desired element isolating width. For example, when a desired element isolating width is 0.5 μm, the openings are formed with a width of approximately 0.3 μm.

Next, the parts of silicon nitride film 3 and silicon oxide film 2 in the openings in photoresist 4 are removed with a plasma etching process, respectively, and Si substrate 1 is etched, thereby forming first isolating trenches 5 with a thickness of approximately 200 nm (FIG. 5(a)).

Subsequently, first photoresist 4 is removed and second photoresist 6 is deposited on silicon nitride film 3. Then, second photoresist 6 is patterned in order to form element isolating areas in the nonvolatile memory region, the high voltage transistor region and a logical circuit region using a photolithography technique (FIG. 5(b)). The openings in second photoresist 6 are formed to have a width set to be substantially the same as a desired element isolating width. For example, the element isolating width in the nonvolatile memory region and high voltage transistor region is set to approximately 0.5 μm, and the element isolating width in the logical circuit region is set to approximately 0.3 μm.

Next, the parts of silicon nitride film 3 and silicon oxide film 2 in the openings in second photoresist 6 are removed with the plasma etching process, respectively, and Si substrate 1 is etched, thereby forming second isolating trenches 7 with a thickness of approximately 300 nm (FIG. 5(c)). At this point, in the nonvolatile memory region and high voltage transistor region, third isolating trenches 5a are formed with a total depth of first isolating trench 5 and second isolating trench 7.

Subsequently, second photoresist 6 is removed, and inside wall thermal oxide films 5b and 7a with a thickness of 20 to 30 nm are deposited on the bottom surfaces and side surfaces of the respective isolating trenches with a thermal oxidation process. Then, plasma oxide film 8 is deposited with a plasma CVD process such that plasma oxide film 8 is embedded in the respective isolating trenches (FIG. 5(d)).

Next, plasma oxide film 8 is planarized with a CMP process to expose patterned silicon nitride film 3 (FIG. 5(e)), and finally, silicon nitride film 3 and silicon oxide film 2 on Si substrate 1 are removed with a wet etching process (FIG. 5(f)).

With the aforementioned steps, field oxide films are formed with thicknesses appropriate respectively for the element isolating areas in the nonvolatile memory region, high voltage transistor region and logical circuit region.

When the element isolation with the field oxide films is completed, tunneling oxide film 9, floating gate electrode 10 and ONO film 11 serving as an insulating film for insulating floating gate electrode 10 from a control gate electrode are formed for a cell transistor in the nonvolatile memory region, and gate oxide films 13 for respective transistors are formed in the high voltage transistor region and logical circuit region. Then, control gate electrode 12 for a cell transistor is formed, and gate electrodes 14 for transistors are formed in the high voltage transistor region and logical circuit region, respectively (FIG. 5(g)). Subsequently, impurity diffusion layers, not shown, which are to serve as sources and drains for respective transistors, are formed, and wiring steps follow.

Therefore, since the field oxide films comprising the oxide films with desired thicknesses can be formed in the nonvolatile memory region and high voltage transistor region by manufacturing a semiconductor integrated circuit device in accordance with the steps of the embodiment, the element isolating performance can be maintained even in the region which requires high withstand voltage.

In addition, since the field oxide film of a transistor for a logical circuit can be formed to have the existing thickness, the element isolating steps need not be changed and a reduced degree of integration can be prevented, thereby allowing the existing manufacturing process and existing design resources to be utilized.

Moreover, the positions of the element isolating areas in the nonvolatile memory region, high voltage transistor region and logical circuit region are determined by the positions of the simultaneously formed second isolating trenches, and the increased number of lower components causes no increase in misalignment of masks for exposure. Thus, a smaller manufacturing margin can be prevented.

(Second Embodiment)

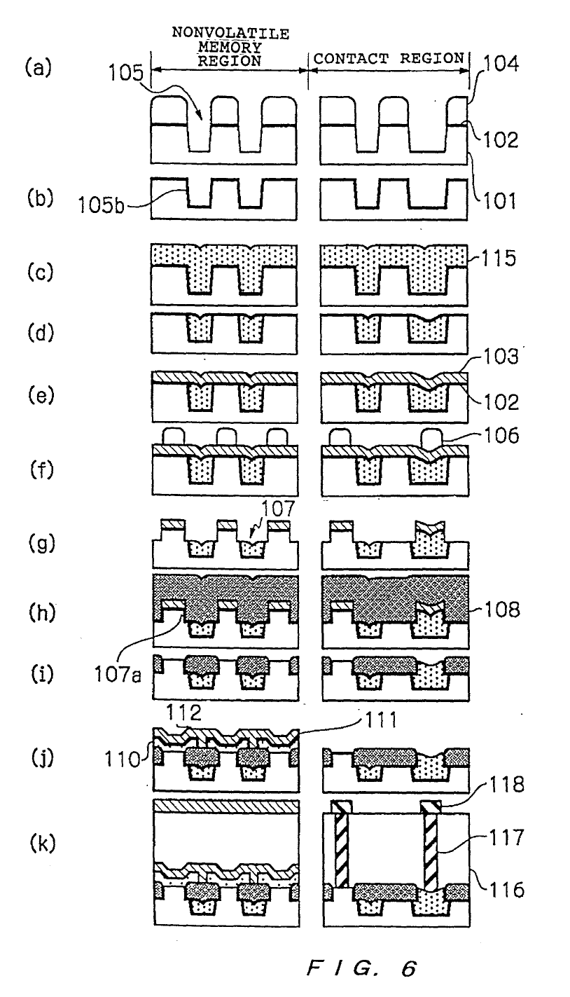

Next, a second embodiment of the element isolating method in a semiconductor integrated circuit device according to the embodiment is described with reference to FIG. 6.

The element isolating method in a semiconductor integrated circuit device of the embodiment is an approach preferable for use in element isolation in a nonvolatile memory region and a high voltage transistor region which require high withstand voltage, in which polysilicon films serving as electrodes are embedded in isolating trenches provided in element isolating areas and a predetermined potential is applied to the polysilicon films to improve element isolating performance. The element isolating method of the embodiment may be used for a logical circuit region to which a normal power supply voltage is applied.

As shown in FIG. 6, in the second embodiment, silicon oxide film 102 with a thickness of approximately 10 nm is first deposited on Si substrate 101, and first photoresist 104 is deposited thereon. First photoresist 104 is then patterned in order to form element isolating areas in a nonvolatile memory region and a high voltage transistor region using a photolithography technique. Subsequently, the part of silicon oxide film 102 in the openings in first photoresist 104 is removed with the plasma etching process, and Si substrate 101 is etched, thereby forming first isolating trenches 105 with a depth of approximately 500 nm in the nonvolatile memory region and high voltage transistor region (FIG. 6(a)). The width of the openings in first photoresist 104 is set to approximately 0.5 μm required for obtaining the depth of first isolating trenches 105.

Next, first photoresist 104 is removed, and inside wall thermal oxide film 105b with a thickness of 20 to 30 nm is deposited on the bottom surfaces and side surfaces of first isolating trenches 105 with the thermal oxidation process (FIG. 6(b)). Then, polysilicon film 115 is deposited over Si substrate 101 with the CVD process such that polysilicon film 115 is embedded in first isolating trenches 105 (FIG. 6(c)). Subsequently, etchback is performed to expose silicon oxide film 102 while polysilicon film 115 remains in first isolating trenches 105 (FIG. 6(d)).

Next, silicon oxide film 102 with a thickness of approximately 10 nm is further deposited to cover polysilicon film 115 embedded in first isolating trenches 105, and silicon nitride film 103 with a thickness of approximately 150 nm is deposited thereon (FIG. 6(e)).

Subsequently, second photoresist 106 is deposited on silicon nitride film 103, and second photoresist 106 is patterned in order to form element isolating areas in the nonvolatile memory region and high voltage transistor region using a photolithography technique. At this point, second photoresist 106 also covers a portion where a contact is formed for connecting polysilicon film 115 embedded in first isolating trench 105 with upper wiring to be formed on an interlayer insulating film at a later step (hereinafter, a region including the portion where a contact is formed is referred to as “contact region”) (FIG. 6(f)). The width of the openings in second photoresist 106 is set to be larger than the opening width in first photoresist 104, for example, approximately 0.7 μm.

Next, the parts of silicon nitride film 103 and silicon oxide film 102 in the openings in second photoresist 106 are removed, and polysilicon film 115 and Si substrate 101 are etched, respectively, thereby forming second isolating trenches 107 with a depth of approximately 300 nm. Then, second photoresist 106 is removed (FIG. 6(g)).

Subsequently, inside wall thermal oxide film 107a with a thickness of 20 to 30 nm is deposited on the bottom surfaces and side surfaces of second isolating trenches 107 with the thermal oxidation process, and then plasma oxide film 108 is deposited with the plasma CVD process such that plasma oxide film 108 is embedded in the respective isolating trenches (FIG. 6(h)).

Next, plasma oxide film 108 is planarized with the CMP process to expose patterned silicon nitride film 103, and finally, silicon nitride film 103 and silicon oxide film 102 on Si substrate 101 are removed, respectively, with the wet etching process (FIG. 6(i).)

With the aforementioned steps, field oxide films comprising the polysilicon films and plasma oxide films embedded in the isolating trenches are formed in the nonvolatile memory region and high voltage transistor region.

When the element isolation with the field oxide films are completed, tunneling oxide film 109, floating gate electrode 110 and ONO film 111 serving as an insulating film for insulating floating gate electrode 110 from a control gate electrode are formed for a cell transistor in the nonvolatile memory region, and gate oxide films 113 for respective transistors are formed in the high voltage transistor region and logical circuit region. In addition, control gate electrode 112 for a cell transistor is formed, and gate electrodes 114 for transistors are formed in the high voltage transistor region and logical circuit region, respectively (FIG. 6(j)). Then, impurity diffusion layers, not shown, which are to serve as sources and drains of respective transistors, are formed.

Interlayer insulating film 116 is deposited to cover them, and contact 117 is formed to connect an electrode of each transistor or polysilicon film 115 embedded in the isolating trench with the surface of interlayer insulating film 116, and finally, upper electrode 188 is formed (FIG. 6(k)).

It should be noted that while FIG. 6 illustrates only the manufacturing procedure of the nonvolatile memory region and the contact region where contact 117 is formed, the high voltage transistor region can also be formed similarly to the nonvolatile memory region.

In addition, while FIG. 6 illustrates an example in which plasma oxide film 108 is formed on polysilicon film 115, the film is not limited to the plasma oxide film, and an oxide film formed from another process (for example, a thermal oxide film) may be used.

As in the embodiment, the polysilicon film is embedded in the isolating trenches provided in the element isolating areas, and a ground potential or a negative voltage is applied to the polysilicon film serving as an electrode (when an N-channel transistor with high withstand voltage is formed in a P-well), thereby making it possible to significantly enhance withstand voltage for isolation between elements as compared with the case where only the oxide film is provided. When a P-channel transistor with high withstand voltage is formed in an N-well, a positive voltage may be applied to the polysilicon film embedded in the isolating trenches.

Typically, the method of obtaining desired withstand voltage for isolation with the aid of the thickness of the oxide film formed in the element isolating area requires greater depths of isolating trenches as a voltage applied to a semiconductor element is higher. Since the width of the openings of the isolating trenches is determined by the embedding properties of the oxide film and increased in proportion to the depth of the isolating trenches, a greater element isolating width is required for enhancing withstand voltage for isolation, resulting in a reduced integration degree of the elements.

In the structure in which the polysilicon film is embedded in the isolating trenches as in the embodiment, desired withstand voltage for isolation can be obtained only by adjusting a voltage applied to the polysilicon film in accordance with the magnitude of a voltage applied to a semiconductor element.

Therefore, desired element isolating performance can be obtained even with a reduced thickness of the oxide film formed in the element isolating area. Thus, even in a semiconductor element to which a higher voltage is applied, for example even when a field oxide film with a thickness of approximately 900 nm is required in the element isolating area, the element isolating performance can be ensured by STI of approximately 500 nm.

In addition, when logical circuits are mounted together, the field oxide film of transistors for the logical circuits can be formed with the existing thickness as in the first embodiment. Thus, the element isolating steps need not be changed and a reduced degree of integration can be prevented to allow the existing manufacturing process and existing design resources to be utilized.

Moreover, the positions of the element isolating areas in the nonvolatile memory region, high voltage transistor region and logical circuit region are determined by the positions of the simultaneously formed second isolating trenches, and the increased number of lower components causes no increase in misalignment of masks for exposure. Thus, a smaller manufacturing margin can be prevented.

While the preferred embodiment of the present invention has been described using specific terms, such description is for illustrative purposes only, and it is to be understood that changes and variations may be made without departing from the spirit or scope of the following claims.

What is claimed is:

1. A method of providing isolation between elements in a semiconductor integrated circuit device in which a plurality of types of semiconductor elements with different applied voltages are mounted together, comprising the steps of:
forming a first isolating trench with a predetermined depth in an element isolating area in a region where high voltage semiconductor elements in which said applied voltage is relatively high are mounted;
forming a second isolating trench shallower than said first isolating trench in a portion where an element isolating area is formed in a region where low voltage semiconductor elements in which said applied voltage is relatively low are mounted, and forming a third isolating trench by etching and removing a portion of walls of said first isolating trench corresponding to the depth of said second isolating trench;
providing isolation between said high voltage semiconductor elements by an oxide film filled into said third isolating trench; and
providing isolation between said low voltage semiconductor elements by an oxide film filled into said second isolating trench.

2. A method of providing isolation between elements in a semiconductor integrated circuit device for providing isolation between semiconductor elements with predetermined withstand voltage for insulation, comprising the steps of;
providing an isolating trench in which a polysilicon film serving as an electrode is embedded and an oxide film with a predetermined thickness is formed on said polysilicon film;
applying a predetermined voltage to said polysilicon film; and
providing isolation between said semiconductor elements by said oxide film and said polysilicon film.

3. A semiconductor integrated circuit device comprising an element isolating area for providing isolation between semiconductor elements with predetermined withstand voltage for insulation, comprising:
an isolating trench formed in said element isolating area with a predetermined depth;
a polysilicon film embedded in said isolating trench with a predetermined thickness and serving as an electrode to which a predetermined voltage is applied; and
an oxide film formed on said polysilicon film with a predetermined thickness without using a thermal oxidation process.

4. The semiconductor integrated circuit device according to claim 3, wherein said semiconductor element is a high voltage semiconductor element to which a relatively high voltage is applied.

5. A method of manufacturing a semiconductor integrated circuit device in which a plurality of types of semiconductor elements with different applied voltages are mounted together, comprising the steps of:
forming a first isolating trench with a predetermined depth in an element isolating area in a region where high voltage semiconductor elements in which said applied voltage is relatively high are mounted;
forming a second isolating trench shallower than said first isolating trench in a portion where an element isolating area is formed in a region where low voltage semiconductor elements in which said applied voltage is relatively low are mounted, and forming a third isolating trench by etching and removing a portion of walls of said first isolating trench corresponding to the depth of said second isolating trench;
filling an oxide film for providing isolation between said high voltage semiconductor elements into said third isolating trench in the region where said high voltage semiconductor elements are mounted; and
filling an oxide film for providing isolation between said low voltage semiconductor elements into said second isolating trench in the region where said low voltage semiconductor elements are mounted.

6. A method of manufacturing a semiconductor integrated circuit device comprising an element isolating area for providing isolation between semiconductor elements with a predetermined withstand voltage for insulation, comprising the steps of:
forming a first isolating trench with a predetermined depth in said element isolating area;
embedding a polysilicon film in said first isolating trench;
forming a second isolating trench shallower than said first isolating trench on said polysilicon film while said polysilicon film with a predetermined thickness is left within said first isolating trench; and
filling an oxide film into said second isolating trench.

7. The method of manufacturing a semiconductor integrated circuit device according to claim 5, wherein said second isolating trench in the region where said high voltage semiconductor elements are mounted is formed to have an opening width which is greater than an opening width of said first isolating trench.

8. The method of manufacturing a semiconductor integrated circuit device according to claim 6, wherein said second isolating trench in the region where said high voltage semiconductor elements are mounted is formed to have an opening width which is greater than an opening width of said first isolating trench.
